(19) United States
(12) Patent Application Publication
(10) Pub. No.: US 2009/0201661 A1
(43) Pub. Date: Aug. 13, 2009

(54) Angle regulating apparatus of a display device

(76) Inventor: Kyung Wook Kim, Kyungsangbuk-do (KR)

Correspondence Address: BIRCH STEWART KOLASCH & BIRCH, PO BOX 747, FALLS CHURCH, VA, 22040-0747, US

(21) Appl. No.: 11/663,547

(22) PCT Filed: Sep. 23, 2004
(86) PCT No.: PCT/KR04/02442

§ 371 Date: Mar. 23, 2007

(51) Int. Cl. H05K 5/00

(52) U.S. Cl. 361/829; 361/679.07

(57) ABSTRACT

There is provided an angle regulating apparatus enabling a user to freely set a rotational angle and direction of a display device installed on a wall or ceiling. The angle regulating apparatus of a display device includes: a support plate coupled to a rear side of the display device; a swivel penetrating a central portion of the support plate and moving together with the support plate, the swivel being curved by a predetermined radius of curvature; a pressure plate installed in a recessed portion of the swivel, for pressurizing the swivel; a swivel holder having a front side recessed by the same radius of curvature as that of the swivel, such that the swivel is installed in the recessed portion; an attachment plate installed in a rear side of the swivel holder, for fixing the display device to a wall or ceiling; a shaft penetrating a front side of the pressure plate from a rear side of the attachment plate; and a nut inserted into an outer periphery of the shaft, for pressurizing the pressure plate. The angle regulating apparatus has an effect that it can be conveniently adjusted to an angle suitable for a user's viewing position.

### TECHNICAL FIELD

The present invention relates to an angle regulating apparatus of a display device, and more particularly, to an angle regulating apparatus enabling a user to freely set a rotational angle and direction of a display device installed on a wall or ceiling.

### BACKGROUND ART

In general, a display device indicates a television (TV) monitor, a computer monitor or the like. In recent years, in the case of the TV monitors, a PDP, an LCD and the like have appeared, and they are fabricated in a flat form having a larger size than that of a general CRT monitor. Since the above flat type monitors can be installed on a wall, use efficiency of inner space is enhanced.

However, when the conventional flat type display devices are installed on a wall, it is difficult to regulate height or direction of the display devices. In other words, since the display devices fixedly attached on a wall do not permit a rotation, when a user watches the display devices standing aside from a front of the display device, a screen on the display devices does not look good.

Accordingly, the conventional flat type display devices have a drawback in that when a viewer who is placed at a predetermined position may inconveniently view a screen of the display device from a front side.

### DISCLOSURE

### Technical Problem

Accordingly, the present invention is directed to a an angle regulating apparatus of a display device that substantially obviates one or more of the problems due to limitations and disadvantages of the related art.

An object of the present invention is to provide an angle regulating apparatus of a display device, which can conveniently regulate an angle even in a state that the display device is installed on a wall. Even if a viewer is placed out of a predetermined angle from a front side of the display device, the viewer can clearly view the display device.

Additional features and advantages of the invention will be set forth in the description which follows, and in part will be apparent from the description, or may be learned by practice of the invention. The objectives and other advantages of the invention will be realized and attained by the structure particularly pointed out in the written description and claims thereof as well as the appended drawings.

### Technical Solution

To achieve these and other advantages and in accordance with the purpose of the present invention, as embodied and broadly described, an angle regulating apparatus of a display device includes: a support plate coupled to a rear side of the display device; a swivel penetrating a central portion of the support plate and moving together with the support plate, the swivel being curved by a predetermined radius of curvature; a pressure plate mounted on a recessed portion of the swivel, for pressurizing the swivel; a swivel holder having a front side recessed by the same radius of curvature as that of the swivel, such that the swivel is mounted on the recessed portion; an attachment plate installed in a rear side of the swivel holder, for fixing the display device to a wall or ceiling; a shaft penetrating a front side of the pressure plate from a rear side of the attachment plate; and a nut inserted into an outer periphery of the shaft, for pressurizing the pressure plate.

According to another aspect of the present invention, an angle regulating apparatus of a display device includes: a rotating member including a support plate coupled to a rear side of the display device, and a swivel penetrating a central portion of the support plate and rotating together with the support plate; a frictional member including a pressure plate installed in a front side of the swivel, and a swivel holder installed in a rear side of the swivel; an attachment plate installed in a rear side of the swivel holder; a shaft penetrating a front side of the pressure plate from a rear side of the attachment plate; a washer part inserted into an outer periphery of the shaft, for adjusting a pressing force of the pressure plate; a nut inserted into a washer part, for pressurizing the washer part; a height adjusting member vertically installed in a rear side of the attachment plate; and a fixing plate installed in an end portion of the height adjusting member and having a predetermined area.

According to a further another aspect of the present invention, an angle regulating apparatus of a display device includes: a support plate coupled to a rear side of the display device; a swivel insertedly penetrated from a front side of the support plate to a rear side thereof; a pressure plate installed in a front side of the swivel, for pressurizing the swivel; a swivel holder installed in a front side of the swivel; an attachment plate installed in a rear side of the swivel holder; a shaft penetrating a front side of the pressure plate from a rear side of the attachment plate; a nut inserted into an outer periphery of the shaft, for pressurizing the pressure plate; and a washer part inserted between the nut and the pressure plate.

### ADVANTAGEOUS EFFECTS

An angle regulating apparatus of a display device according to the present invention can be adjusted to an angle suitable for a user's viewing position.

Also, the angle regulating apparatus is coupled to a height adjusting member and a fixing plate or a base, such that it can be installed on a bottom or in a space spaced apart from a ceiling by a predetermined distance. Accordingly, the angle regulating apparatus has an effect that performs a tilt-type stand function to which an existing hinge is applied.

Further, the height adjusting member itself can rotate and an angle of the display device can be regulated using a swivel of the angle regulating apparatus. Therefore, it is possible for the user to clearly watch the display device at any angles.

### DESCRIPTION OF DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a rear perspective view of an angle regulating apparatus mounted on a display device according to the present invention;

FIG. 2 is an exploded perspective view of the angle regulating apparatus shown in FIG. 1;

FIG. 3 is a cross-sectional view of the angle regulating apparatus shown in FIG. 1;

FIG. 4 is a side sectional view of the state when the display device coupled to the angle regulating apparatus is installed on the wall;

FIGS. 5 to 8 are views illustrating another rotation states of the angle regulating apparatus according to the present invention;

FIGS. 9 and 10 are perspective views of a swivel in an angle regulating apparatus according to another embodiment of the present invention;

FIG. 11 illustrates an exemplary application of an angle regulating apparatus for a display device according to the present invention; and

FIG. 12 illustrates another application of an angle regulating apparatus for a display device according to the present invention.

### BEST MODE

Hereinafter, preferred embodiments of the present invention will be described in detail with reference to accompanying drawings.

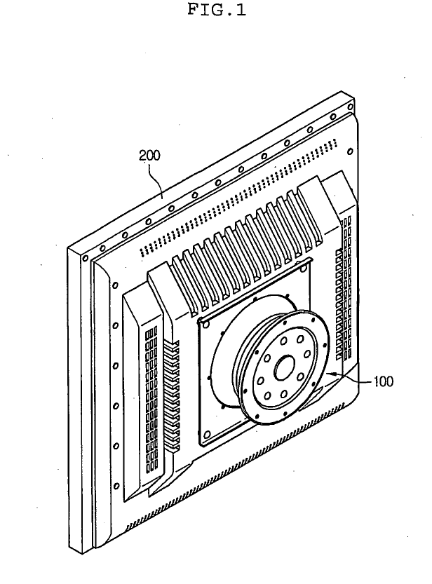

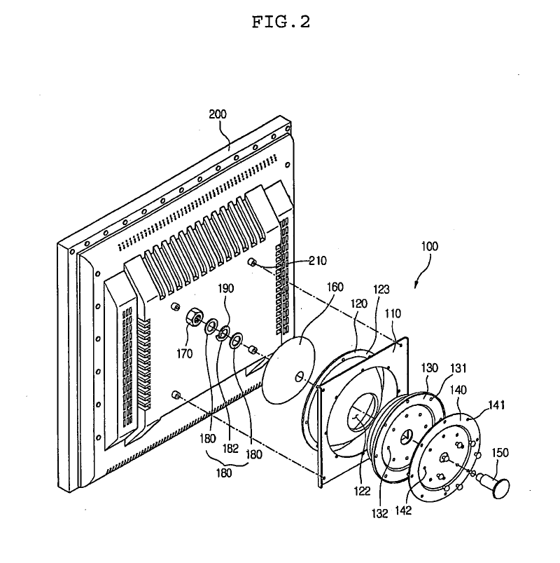

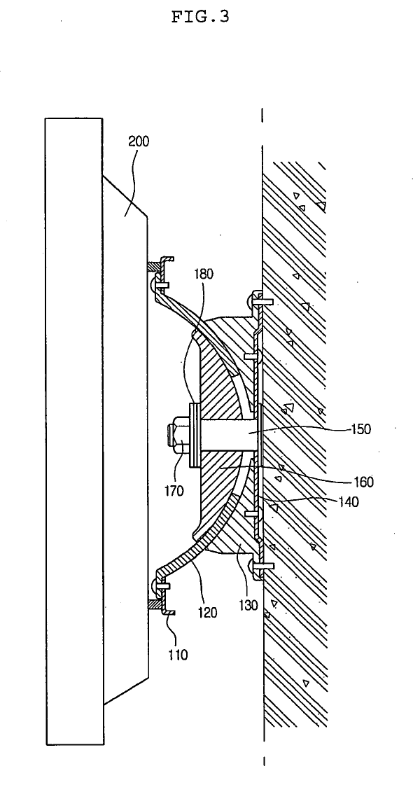

FIG. 1 is a rear perspective view of an angle regulating apparatus mounted on a display device according to the present invention, FIG. 2 is an exploded perspective view of the angle regulating apparatus shown in FIG. 1, and FIG. 3 is a cross-sectional view of the angle regulating apparatus shown in FIG. 1.

Referring to FIGS. 1 to 3, an angle regulating apparatus 100 according to the present invention is mounted on a rear side of a display device 200. The angle regulating apparatus 100 is installed on a wall and allows the display device 200 to rotate by a predetermined angle.

In more detail, the angle regulating device 100 includes: a support plate 110 coupled to the rear side of the display device 200 by means of a coupling member; a hemispherical swivel 120 insertedly penetrated from a front side of the support plate 110 to a rear side thereof; a pressure plate 160 mounted on a recess formed at an inner side of the swivel 120, for pressurizing the swivel 120; and a swivel holder 130 disposed at a rear side of the swivel 120 and in which a curved portion of the swivel is installed.

Also, the angle regulating apparatus 100 further includes: an attachment plate 140 mounted on a rear side of the swivel holder 130, for enabling the angle regulating apparatus 100 to be installed on a wall; a shaft 150 penetrating a center of the pressure plate 160; a coupling nut 170 inserted into an outer periphery of the shaft 150 to couple the above-described elements; and a washer part 180 inserted before the coupling nut 170, for controlling a compression force between the pressure plate 160 and the swivel holder 130.

In more detail, the swivel 120 is formed in an approximately hemispherical shape. A flange 123 extending a radial direction by a predetermined width is formed at an edge portion of the swivel 120. At least one coupling hole 121 is formed so that the coupling member can be inserted along a central portion of the flange 123. The flange 123 is installed in a front side of the support plate 110. A penetrating opening 122 is formed at a central portion of the swivel 120. The penetrating opening 122 is provided by cutting the central portion of the swivel 120 in a circular shape having a predetermined diameter. The shaft 150 penetrates the penetrating opening 122. An operation range of the swivel 120 is determined by a size of the penetrating opening 122. In other words, a rotational angle of the display device mounted on the angle regulating device 100 is determined by the size of the penetrating opening 122.

Also, the pressure plate 160 mounted on the front side of the swivel 120 is formed in a dish shape having the same curvature as the inner periphery of the swivel 120. The shaft 150 penetrates the central portion of the pressure plate 160. Accordingly, the inner periphery of the swivel 120 and the outer periphery of the pressure plate 160 come into contact with each other and thus a frictional force is generated. A magnitude of the frictional force is determined depending on a size and weight of the display device 200.

In addition, the swivel holder 130 mounted on the rear side of the swivel 120 is formed in a cylindrical shape having a predetermined diameter and length. A front side of the swivel holder 130 is recessed with the same radius of curvature as the curved surface of the swivel 120. A penetrating hole which the shaft 150 penetrates is formed at a central portion of the swivel holder 130. The swivel 120 is mounted on the end portion of the swivel holder 130, and the attachment plate 140 is attached to an opposite end portion. In more detail, a diameter of the end portion to which the attachment plate 140 is attached is larger than that of the end portion on which the swivel 120 is mounted. Therefore, at least one coupling hole 131 is formed so that the coupling member can be penetrated along the periphery. A plurality of coupling holes 141 corresponding to the coupling holes 131 are formed at the attachment plate 140. The coupling member penetrates the coupling holes 131 and 141 such that the attachment plate 140 and the swivel holder 130 are coupled together. The coupling member penetrating the coupling holes 131 and 141 penetrates a wall on which the angle regulating apparatus 100 is mounted.

Meanwhile, a plurality of coupling holes 132 are formed in a circular pattern between the center of the swivel holder 130 and the coupling holes 131. Also, the attachment plate 140 includes a plurality of coupling holes 142 formed at positions corresponding to the coupling holes 132. The coupling member insertedly penetrates the coupling holes 132 and 142 such that the swivel holder 130 and the attachment plate 140 are coupled together. Here, the coupling member penetrating the coupling holes 132 and 142 is inserted in a direction from the attachment plate 140 toward the swivel holder 130.

An amount of rotation of the display device 200 is determined by the diameter of the swivel holder 130 on which the swivel 120 is mounted. In other words, as the diameter of the swivel holder 130 increases, the end portion of the swivel holder 130 and the flange of the swivel 130 get closer. A state that the swivel 120 can rotate to the maximum is a state that the end portion of the swivel holder 130 is in contact with the support plate 110. Accordingly, as the diameter of the swivel holder 130 decreases, a rotatable angle of the swivel 120 increases. As a result, the rotational angle of the display device 200 increases.

Also, a penetrating part having the same diameter as the end portion of the swivel 120 is formed at the central portion of the support plate 110 on which the flange of the swivel 120 is mounted. As described above, the swivel penetrates the penetrating part and is mounted on the swivel holder 130. The support plate 110 and the swivel 120 are coupled together by means of the coupling member penetrating the coupling hole 121 formed at the flange 123. At least one coupling boss 210 is inserted between the support plate 110 and the display device 200, and the coupling member such as a screw penetrates the coupling boss 210, such that the display device 200 and the support plate 110 are coupled together. Here, it is desirable that the coupling boss 210 is installed in a front edge portion of the support plate 110. A shape of the support plate 110 is not limited in the embodiments of the present invention. That is, the support plate 110 can be formed in various shapes.

Further, as described above, the pressure plate 160 installed in the front recessed portion of the swivel 120 is formed with the same curvature as that of the swivel 120, such that it is in contact with the inner periphery of the swivel 120. A hole which the shaft 150 penetrates is formed at the central portion of the pressure plate 160. The pressure plate 160 and swivel holder 130 are integrally fixed by the shaft 150. Even when the swivel 120 is rotating, the fixed state between the pressure plate 160 and the swivel holder 130 is maintained.

Meanwhile, the washer part 180 installed in the front side of the pressure plate 160 and inserted in the outer periphery of the shaft 150 includes flat washers 181 and a spring washer 182. In detail, the flat washers 181 form a ring-shaped closed curve band having a predetermined outer diameter. Although the spring washer 182 has a predetermined outer diameter just like the flat washers 181, the spring washer 182 has a spiral shape, such that one end and the other end are stepped by a predetermined interval. Accordingly, the spring washer 182 is characterized in that it does not form a closed curve. Also, the spring washer 182 has a predetermined elastic coefficient.

In more detail, the flat washers 181 are inserted into the front and rear of the spring washer 182, and a nut 170 is inserted into the front of the flat washer 181 which is inserted into the front of the spring washer 182. The elements of the angle regulating apparatus 100 are tightly coupled together by the rotation of the nut 170. Here, the magnitude of the frictional force generated in the front and rear sides of the swivel 120 is determined by an amount of rotation occurring when the nut 170 is inserted into the shaft 150 and then rotated. As the nut 170 is tightened, the stepped distance between one end portion and the other end portions of the spring washer 182 becomes narrow. Accordingly, a pressure at which the pressure plate 160 presses the swivel 120 is finely adjusted by the elastic force of the spring washer. In other words, as a thickness or weight of the display device 200 increases, the tightening force of the nut 170 increases, and the elastic force generated by the spring washer 182 is transferred to the pressure plate 160.

The user moves the display device 200 up and down and/or right and left so as to regulate the angle of the display device 200 mounted on the angle regulating apparatus 100 assembled in the above-described order. If so, the support plate 110 integrally coupled to the rear side of the display device 200 is also moved together. Simultaneously, the swivel 120 integrally coupled to the support plate 110 is rotated on the swivel holder 130. A predetermined frictional force acts between the front side of the swivel 120 and the pressure plate 160, the rear side of the swivel 120 and the recessed portion of the swivel holder 130. Thus, the display device 200 does not move in a state that it rotates by a predetermined angle, even though the user moves off from the display device. In addition, the display device 200 can rotate around the shaft 150, because the penetrating opening 122 is formed at the rear side of the swivel 120 and the shaft 150 penetrates the penetrating opening 122. Accordingly, the display device 200 having a rectangular shape can be fixed horizontally or vertically.

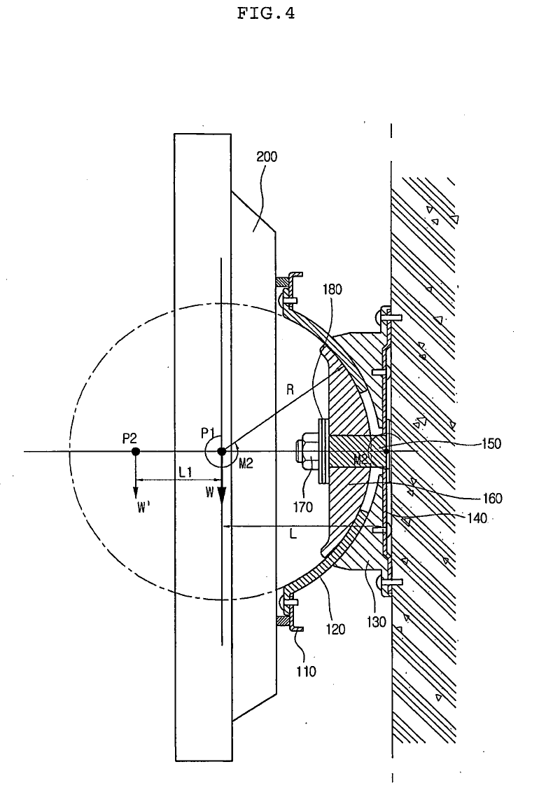

FIG. 4 is a side sectional view of the state when the display device coupled to the angle regulating apparatus is installed on the wall.

Referring to FIG. 4, when the display device 200 is installed on the wall, the weight of the display device 200 acts downwards at a point P1 corresponding to a center of gravity of the display device 200 mounted on the angle regulating apparatus 100. A moment M1 corresponding to a product of a distance L from the wall to the point P1 and the weight W acts on the angle regulating apparatus 100.

Meanwhile, if the center of gravity acts on a point P2 spaced apart from the point P2 by a predetermined distance, a rotational moment M2 corresponding to a product of a distance L1 from the point P1 to the point P2 and the weight W of the display device 200 acts on the center P1 of rotation of the display device 200. Here, the point P2 on which the center of gravity acts may be formed in a left or right side with reference to FIG. 4. This is determined by a size of the swivel 120 or a thickness of the display device 200.

In order to prevent the display device 200 from rotating spontaneously due to the rotational moment, the nut 170 is tightened so that a frictional force equal to or greater than the rotational moment M2 acts on the front and rear sides of the swivel 120. If so, the washer member 180 pressurizes the pressure plate 160, and the pressure plate 160 and the swivel holder 130 pressurize the front and rear sides of the swivel 120, resulting in a frictional force equal to or greater than the rotational moment M2.

Accordingly, a magnitude of the frictional force acting on the front and rear sides of the swivel 120 is determined by a magnitude of the rotational force M2. Therefore, it is desirable that the center of gravity of the display device 200 acts on the center of radius of curvature of the swivel 120, that is, the same point as the center of rotation.

According to the angle regulating apparatus 100 of the present invention, the point which the center of gravity of the display device 200 acts on can be formed maximally close to the rotational center P1 of the display device by properly adjusting the radius of curvature of the swivel 120 depending on the points of the center of gravity acting on the display device 200.

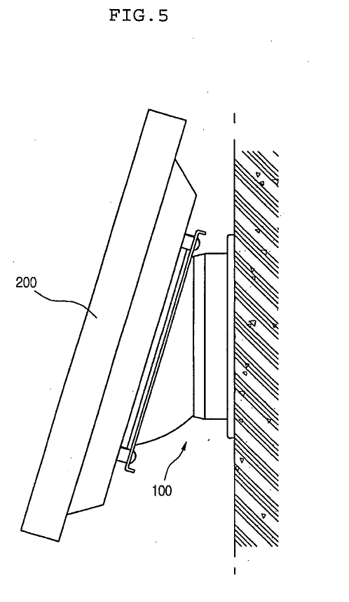

FIGS. 5 to 8 are views illustrating another rotation states of the angle regulating apparatus according to the present invention.

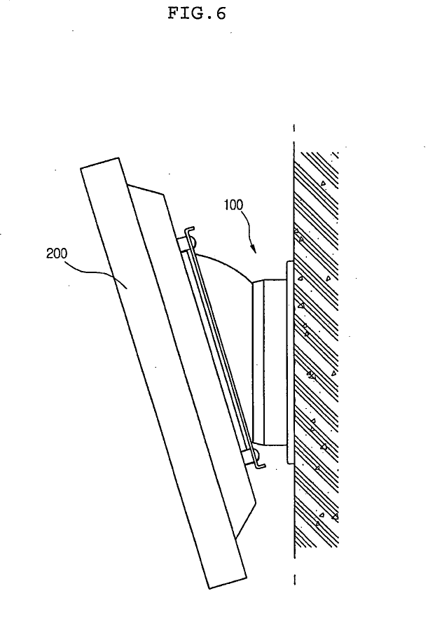

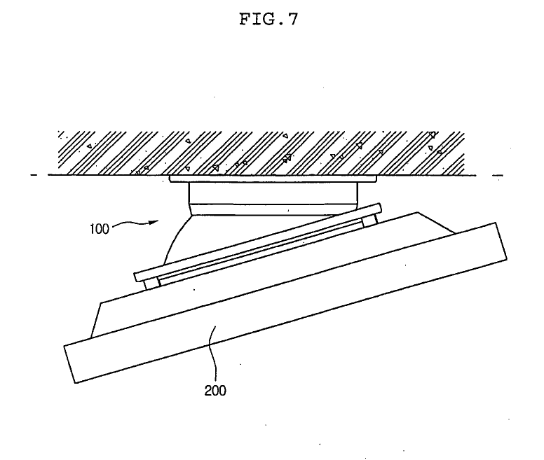

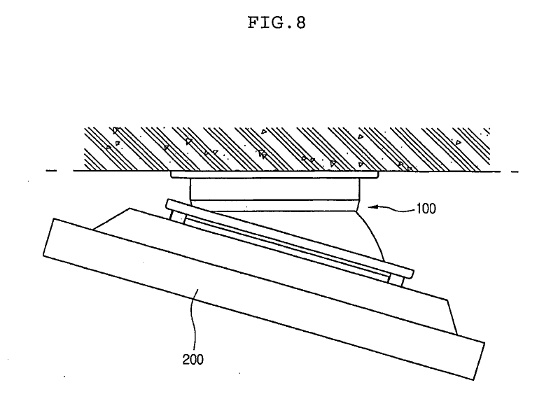

In detail, FIG. 5 is a right side view of a state when the display device 200 is rotated upwards, and FIG. 6 is a right side view of a state when the display device 200 is rotated downwards. FIG. 7 is a plan view of a state when the display device 200 is rotated in a right direction, and FIG. 8 is a plan view of a state when the display device 200 is rotated in a left direction.

As shown in the drawings, the display device 200 can be freely rotated in an omni-direction. Also, the display device 200 can be freely rotated around the shaft 150 in a clockwise or counterclockwise direction.

### MODE FOR INVENTION

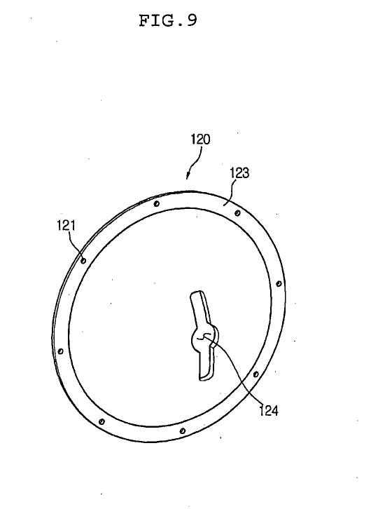

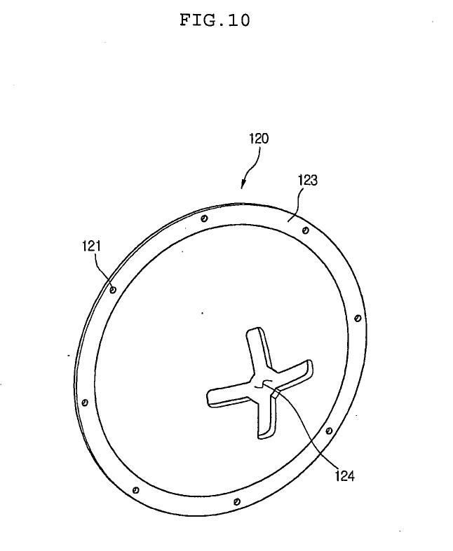

FIGS. 9 and 10 are perspective views of a swivel in an angle regulating apparatus according to another embodiment of the present invention.

Referring to FIGS. 9 and 10, a rotatable direction of a display device 200 is determined by a shape of a penetrating opening formed at a lower portion of a swivel 120, which is an element of an angle regulating apparatus 100 according to the present invention.

In more detail, when the display device 200 installed on a wall has only to rotate in up/down or right/left direction, the penetrating opening 124 may be formed in a shape of a straight line having a predetermined width and length. In order to allow the display device 200 to rotate in up/down and right/left directions, the penetrating opening 124 may be formed in a “+” shape.

In other words, a moving path of the shaft 150 is determined by the shape of the penetrating opening 124.

The shape of the penetrating opening 124 is not limited to the embodiment of the present invention, and the penetrating opening 124 can be formed in various shapes according to the rotating direction of the display device 200.

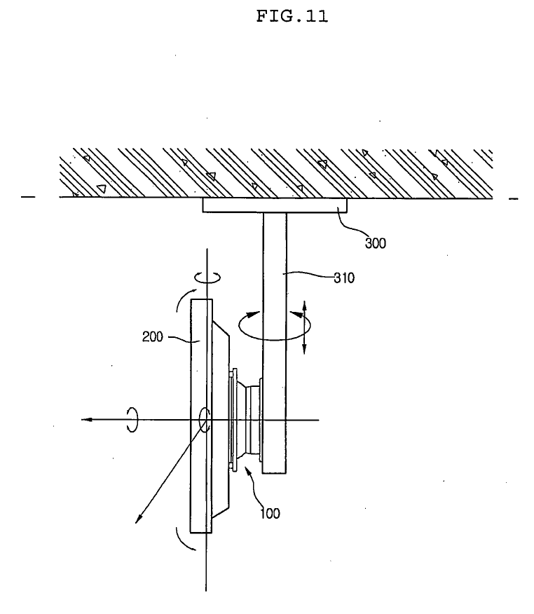

FIG. 11 illustrates an exemplary application of an angle regulating apparatus for a display device according to the present invention.

Referring to FIG. 11, the angle regulating apparatus 100 of the display device according to the present invention can be installed in a position extended vertically from a ceiling by a predetermined length by means of a height adjusting member 310 and a fixing plate 300. The fixing plate 300 allows the height adjusting member 310 to be fixed to the ceiling.

The height adjusting member 310 is a member to perform a tilt function. Using the height adjusting member 310, the user can adjust the height of the display device 200. The height adjusting member 310 can be rotated by 360°.

Accordingly, a position of the display device 200 can be freely set depending on a position of the user. When the display device 200 is formed in a rectangular shape, the display device 200 can be installed vertically or horizontally through its rotation.

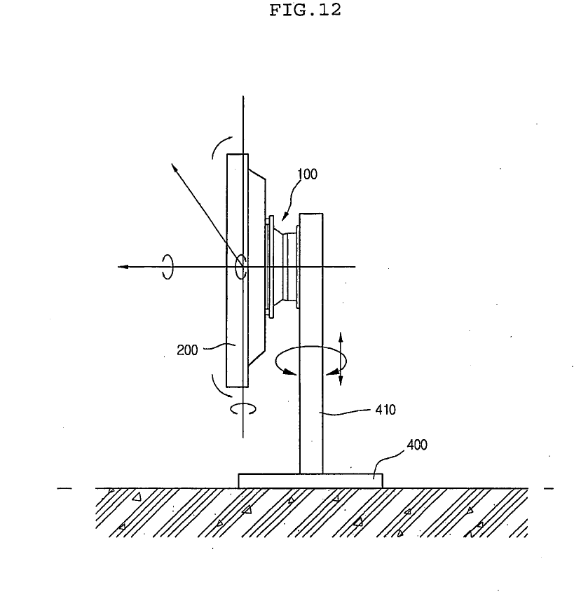

FIG. 12 illustrates another application of an angle regulating apparatus for a display device according to the present invention.

Referring to FIG. 12, an angle regulating apparatus 100 according to the present invention can be coupled to an upright height adjusting member 410 of a predetermined length and a base 400. The base 400 is coupled to a lower portion of the height adjusting member 400 and placed on a bottom.

In detail, the height adjusting member 410 is installed on a rear surface of the attachment plate 140 of the angle regulating apparatus 100, and the base 400 is installed on a lower portion of the height adjusting member 410. Thus, a stand function can be performed.

In more detail, the angle regulating apparatus 100 mounted on a rear surface of the display device 200 performs a hinge function, which is provided in a related art tilt-type angle regulating apparatus. However, unlike the hinge allowing the display device to rotate only in an up/down direction, the angle regulating apparatus 100 according to the present invention can achieve three-dimensional rotation.

Further, as shown in FIG. 11, the height adjusting member 410 itself can adjust its height and rotate.

Since the height adjusting member 410 itself can rotate, a screen of the display device 200 can be viewed at all directions.

While the present invention has been described and illustrated herein with reference to the preferred embodiments thereof, it will be apparent to those skilled in the art that various modifications and variations can be made therein without departing from the spirit and scope of the invention. Thus, it is intended that the present invention covers the modifications and variations of this invention that come within the scope of the appended claims and their equivalents.

### INDUSTRIAL APPLICABILITY

The angle regulating apparatus of the display device can be installed computer monitors, PDP or LCD monitors and the like. Since the screen of the monitor can be clearly viewed at various angles, the industrial applicability is very high.

1. An angle regulating apparatus of a display device, comprising:
a support plate coupled to a rear side of the display device;
a swivel penetrating a central portion of the support plate and moving together with the support plate, the swivel being curved by a predetermined radius of curvature;
a pressure plate mounted on a recessed portion of the swivel, for pressurizing the swivel;
a swivel holder having a front side recessed by the same radius of curvature as that of the swivel, such that the swivel is mounted on the recessed portion;
an attachment plate installed in a rear side of the swivel holder, for fixing the display device to a wall or ceiling;
a shaft penetrating a front side of the pressure plate from a rear side of the attachment plate; and
a nut inserted into an outer periphery of the shaft, for pressurizing the pressure plate.

2. The angle regulating apparatus according to claim 1, wherein the swivel includes a penetrating opening at the recessed portion, the penetrating opening having a predetermined diameter.

3. The angle regulating apparatus according to claim 1, wherein the swivel includes a hole at the recessed portion, the hole being formed in a shape of a straight line having a predetermined width and length.

4. The angle regulating apparatus according to claim 1, wherein the swivel includes angle regulating holes formed crossing each other at the recessed portion.

5. The angle regulating apparatus according to claim 1, further comprising at least one ring-shaped washer inserted into a front outer periphery of the shaft to pressurize the pressure plate.

6. The angle regulating apparatus according to claim 1, further comprising a spring washer inserted into a front outer periphery of the shaft to pressurize the pressure plate, the spring washer being formed in a spiral shape such that one end portion and the other end portion of the spring washer are spaced from each other.

7. The angle regulating apparatus according to claim 1, further comprising a washer member inserted between the nut and the pressure plate to adjust a frictional force acting on the swivel, wherein the washer member includes:
a spring washer formed in a spiral shape and having a predetermined elastic coefficient; and
a flat washer formed in a ring shape and inserted at front and rear sides of the spring washer.

8. The angle regulating apparatus according to claim 1, wherein the swivel includes a flange formed at an edge portion along a periphery with a predetermined radial distance, the flange being mounted on a front side of the support plate.

9. The angle regulating apparatus according to claim 1, wherein a rotation center of the swivel and a center of gravity of the display device coupled to the support plate are placed on the same vertical line.

10. The angle regulating apparatus according to 1, further comprising at least one boss having one end portion coupled to a rear side of the display device and the other end portion coupled to a front side of the support plate, the boss having a predetermined length.

11. An angle regulating apparatus of a display device, comprising:
a rotating member including a support plate coupled to a rear side of the display device, and a swivel penetrating a central portion of the support plate and rotating together with the support plate;
a frictional member including a pressure plate installed in a front side of the swivel, and a swivel holder installed in a rear side of the swivel;
an attachment plate installed in a rear side of the swivel holder;
a shaft penetrating a front side of the pressure plate from a rear side of the attachment plate;
a washer part inserted into an outer periphery of the shaft, for adjusting a pressing force of the pressure plate;
a nut inserted into a washer part, for pressurizing the washer part;
a height adjusting member vertically installed in a rear side of the attachment plate; and
a fixing plate installed in an end portion of the height adjusting member and having a predetermined area.

12. The angle regulating apparatus according to claim 11, wherein a length the height adjusting member is adjustable in an up and down direction.

13. The angle regulating apparatus according to claim 11, wherein the height adjusting member is rotatable.

14. The angle regulating apparatus according to claim 11, wherein the fixing plate is installed on a ceiling.

15. The angle regulating apparatus according to claim 11, wherein the fixing plate is installed on a bottom and performs a stand function together with the height adjusting member.

16. An angle regulating apparatus of a display device, comprising:
a support plate coupled to a rear side of the display device;
a swivel insertedly penetrated from a front side of the support plate to a rear side thereof;
a pressure plate installed in a front side of the swivel, for pressurizing the swivel;
a swivel holder installed in a front side of the swivel;
an attachment plate installed in a rear side of the swivel holder;
a shaft penetrating a front side of the pressure plate from a rear side of the attachment plate;
a nut inserted into an outer periphery of the shaft, for pressurizing the pressure plate; and
a washer part inserted between the nut and the pressure plate.

17. The angle regulating apparatus according to claim 16, wherein the swivel is curved with a predetermined radius of curvature, and the swivel holder is recessed with the same radius of curvature of the swivel.

18. The angle regulating apparatus according to claim 16, wherein the attachment plate is installed on a ceiling or a wall.

19. The angle regulating apparatus according to claim 16, wherein the swivel holder is formed in a cylindrical shape having a predetermined diameter and length.

20. The angle regulating apparatus according to claim 16, wherein a distance from an inner periphery of the swivel to a center of gravity of the display device is equal to a radius of gravity of the swivel.

21. The angle regulating apparatus according to claim 16, wherein the washer part has a predetermined elastic force so as to finely adjust a magnitude of a frictional force acting on front and rear sides of the swivel.
